(19) United States
(12) Patent Application Publication
(10) Pub. No.: US 2009/0236715 A1
(43) Pub. Date: Sep. 24, 2009

(54) SEMICONDUCTOR PACKAGE STRUCTURE WITH LAMINATED INTERPOSING LAYER

(76) Inventors: Kazuaki Ano, Oita (JP); Frank Yu, Chung Ho (TW); Wei Lung Hsu, Shu Lin (TW)

Correspondence Address: TEXAS INSTRUMENTS INCORPORATED, P O BOX 655474, M/S 3999, DALLAS, TX, 75265, US

(21) Appl. No.: 12/050,722

(22) Filed: Mar. 18, 2008

(51) Int. Cl. H01L 23/00; H01L 21/50

(52) U.S. Cl. 257/678; 257/777; 438/109; 257/E23.001; 257/E21.499

(57) ABSTRACT

The invention relates to microelectronic semiconductor chip assemblies having vertically stacked layers. In a disclosed example of a preferred embodiment, a vertically stacked semiconductor chip assembly includes a first semiconductor chip affixed to the surface of a substrate. A laminated interposing layer therebetween includes a first adhesive material and a second adhesive material, at least one of the adhesive materials adapted to capturing debris. Methods are disclosed for making a vertically stacked semiconductor chip assemblies by joining first and second adhesive materials to form a laminated interposing layer between a first chip and second chip or substrate. In preferred embodiments of the invention, the interposing layer includes polyimide film and one adhesive material of relatively low elasticity, and another adhesive material having relatively high elasticity.

### TECHNICAL FIELD

The invention relates to electronic semiconductor chip packages and manufacturing. More particularly, the invention relates to vertically stacked semiconductor chip assemblies with improved interposing layers between semiconductor chips and underlying layers, and to associated methods for their manufacture.

### BACKGROUND OF THE INVENTION

There is an ongoing need to minimize the size of electronic apparatus. At the same time, the demand for increased features results in an increase in the number of components in a given package. Efforts are continuously being made to design and manufacture chips and packages with reduced area, but attempts to increase density while reducing area eventually reach a practical limit. As designers attempt to maximize the use of substrate, semiconductor chip, and system area, vertical stacking of system components becomes increasingly attractive.

Generally, semiconductor chip packages are constructed in layered assemblies by mounting a semiconductor chip to the surface of a substrate or another packaged semiconductor chip, often with exposed surface contacts provided for making electrical connections. In such assemblies, it is known in the arts to mount one semiconductor chip on another chip or substrate using an interposing layer made from a film provided with adhesive surfaces, or an adhesive applied as a semi-viscous paste and allowed to cure to form a solid interposing layer.

It is known in the arts to go to great lengths to keep the assembly process free of contaminants such as debris particles from the surrounding environment. Despite the best of such efforts, however, debris may nevertheless be introduced into the assembly through imperfect cleaning of chips or other assembly components. The presence of debris particles in completed semiconductor chip package assemblies often results in defects leading to lower yield from manufacturing processes, and increased costs. Due to these and other technological problems, improved vertically stacked semiconductor chip assemblies less susceptible to debris defects, and methods for their manufacture, would be useful and advantageous contributions to the art. The present invention is directed to overcoming, or at least reducing, problems present in the prior art, and contributes one or more heretofore unforeseen useful advantages.

### SUMMARY OF THE INVENTION

In carrying out the principles of the present invention, in accordance with preferred embodiments thereof, the invention provides novel and useful improvements for vertically stacked semiconductor chip assemblies. Through diligent study and persistent experimentation it has been determined that in spite of significant efforts made to exclude contaminants from the assembly process, problems associated with techniques known in the art include a tendency to trap debris in locations detrimental to the operation of the assembly.

It has been observed that, using assembly approaches common in the arts, often one or more semiconductor chip in a stack has debris such as minute silicon particles present despite efforts to clean stack components prior to assembly. The debris particles observed are generally a product of the saw singulation of individual chips mass-produced on a wafer. These debris particles, relatively harmless when present on an inactive area of a chip surface, are sometimes moved to an active electrical contact area by handling, and/or by the application of chip attach adhesive interposed between stack components during package assembly. The result may be an electrical short, open circuit, current leakage, increased resistance, increased parasitic capacitance, a poorly bonded contact, or other problem due to the ill-placed debris particle(s). Ongoing efforts to eliminate the presence of debris particles are not one hundred percent successful. FIGS. 1A and 1B (prior art) provide a simplified cutaway side view generally representative of problems identified and addressed by the applicants. A vertically stacked semiconductor chip assembly 1 includes a first chip 2 and a second chip 3. An interposing layer 4, such as an adhesive film or a curable semi-viscous adhesive paste, is used to join the chips 2, 3. In this example, a conductive interconnect layer 5 is shown at the surface of the first chip 2. Debris particles 6, present for example on the upper chip 3 in the drawing, may become dislodged from the chip 3 during handling and may become permanently bonded to a debris-sensitive location, such as the gap 7 separating electrical paths of the interconnect layer 5 as shown, with the potential to cause mischief in the nature described above. The invention addresses the debris problem by using interposing layers not only for joining adjacent layers, but also for shielding surfaces from debris during assembly and for capturing debris particles to prevent them from being inadvertently moved to harmful locations.

According to one aspect of the invention, in an example of a preferred embodiment, a semiconductor chip assembly using the invention includes a semiconductor chip affixed to the surface of a substrate with a laminated interposing layer therebetween. The laminated interposing layer includes a first adhesive material and a second adhesive material.

According to another aspect of the invention, in a preferred embodiment, a semiconductor chip assembly includes a laminated interposing layer between two assembly components wherein at least one adhesive material of the laminated interposing layer includes an adhesive film.

According to another aspect of the invention, in a vertically stacked semiconductor chip assembly incorporating an interposing layer as described above, in a preferred embodiment, a first semiconductor chip is affixed to a second semiconductor chip with a laminated interposing layer therebetween, including a first adhesive material and a second adhesive material.

According to yet another aspect of the invention, in an example of a preferred embodiment, a vertically stacked semiconductor chip assembly includes a laminated interposing layer as described above wherein at least one adhesive material is a curable semi-viscous adhesive.

According to still another aspect of the invention, an exemplary method for making a vertically stacked semiconductor chip assembly includes the steps of applying a first adhesive material to a surface of a first semiconductor chip and applying a second adhesive material to a surface of a substrate. Thereafter, the first and second adhesive materials are joined to form a laminated interposing layer between the first chip and the substrate.

The invention has advantages including but not limited to one or more of the following: prevention of debris movement into disadvantageous locations during semiconductor package assembly; capturing debris in less detrimental locations during semiconductor package assembly; high conformability of interposing layers between stack components; excellent adhesion of interposing layers to adjacent stack components; reduced defects in completed assemblies; and reduced cost. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIGS. 1A and 1B (prior art) provide cutaway side views representative of an example of problems in the art with respect to vertically stacked semiconductor chip assemblies and methods for their manufacture;

FIG. 2A is a cutaway side view of an example of portions of a preferred embodiment of a vertically stacked semiconductor chip assembly and steps for its manufacture according to the invention;

FIG. 2B is a cutaway side view of an example of a preferred embodiment of a vertically stacked semiconductor chip assembly and steps for its manufacture according to the invention;

FIG. 2C is a cutaway side view of an example of a preferred embodiment of a vertically stacked semiconductor chip assembly and steps for its manufacture according to the invention;

FIG. 3A is a cutaway side view illustrating an example of an alternative embodiment of portions of a vertically stacked semiconductor chip assembly and steps in its manufacture according to the invention; and

FIG. 3B is a cutaway side view of an example of an alternative preferred embodiment of a vertically stacked semiconductor chip assembly and steps in its manufacture according to the invention.

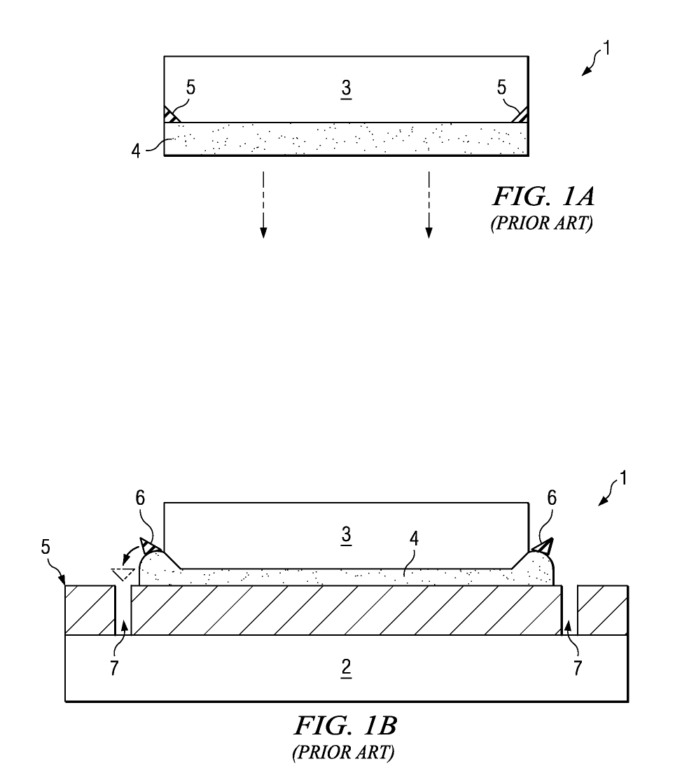

The drawings are not to scale, and some features of embodiments shown and discussed are simplified or amplified for illustrating principles and features, as well as anticipated and unanticipated advantages of the invention.

### DESCRIPTION OF PREFERRED EMBODIMENTS

While the making and using of various exemplary embodiments of the present invention are discussed herein, it should be appreciated that the present invention provides inventive concepts which can be embodied in a wide variety of specific semiconductor chip package contexts. It should be understood that the invention may be practiced with vertically stacked semiconductor package-on-package (POP) assemblies, similarly stacked assemblies, and associated manufacturing processes of various types and materials without altering the principles of the invention. For purposes of clarity, detailed descriptions of functions and systems familiar to those skilled in the semiconductor chip, packaging, and manufacturing arts are not included.

In general, the invention provides vertically stacked semiconductor chip assemblies using laminated interposing layers, which preferably include at least one film layer, for vertically coupling layers of the stack assembly. Features of the invention are advantageous in terms of reducing detrimental effects of debris in stacked semiconductor assemblies, and even in providing potential benefits in terms of increased mechanical strength and durability.

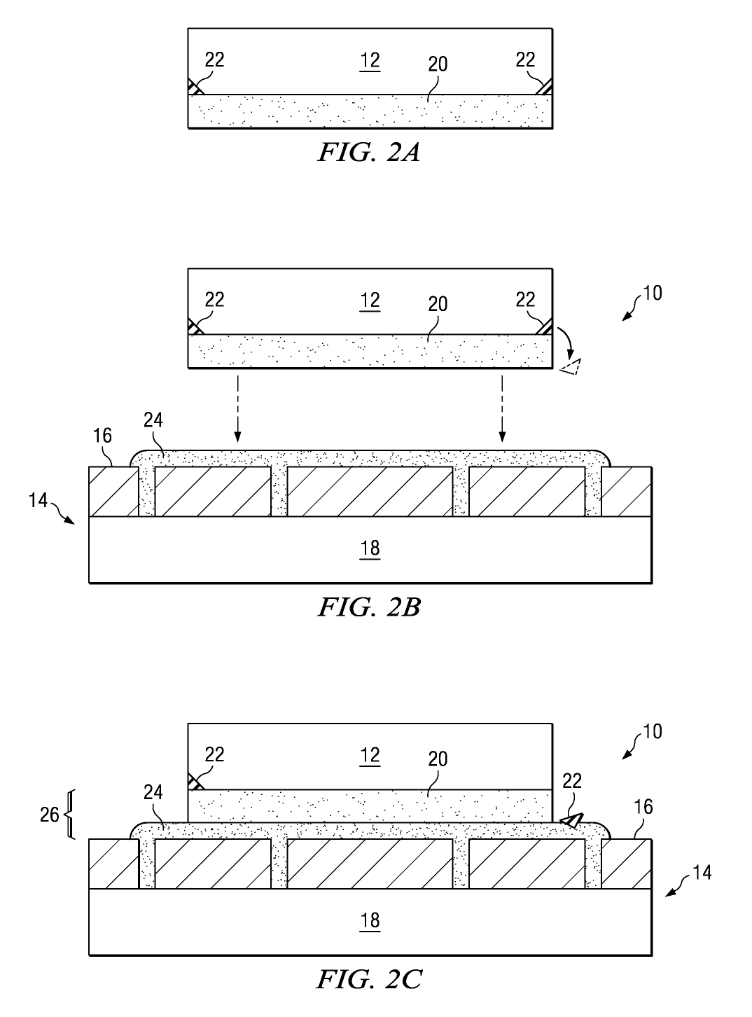

Referring initially to FIGS. 2A through 2C, an example of a vertically stacked semiconductor chip assembly 10, and steps in its manufacture according to a preferred embodiment of the invention, are shown in a series of simplified cutaway views. In FIG. 2A, a semiconductor chip 12 is shown. The chip 12 is preferably an integrated circuit chip prepared for placement on the surface of a suitable substrate 14, shown in FIG. 2B. In this example, the substrate 14 has a metal interconnect layer 16 located over a dielectric layer 18. In this example of a preferred embodiment of a package 10 according to the invention, the top metal layer 16 is a Bond Over Active Circuit (BOAC) layer made from metal, such as copper, and used for making electrical connections, although other conductive material may be used. A first chip attach adhesive material, in this case an adhesive film 20, is affixed to one side of the chip 12. Often, minute debris particles 22 will be present on the chip 12 despite efforts at removal and prevention. Although the presence of debris particles is all but inevitable in many cases, the presence of debris particles is not essential in every case for the practice of the invention. The substrate 14 may be dedicated solely to the mounting of chips for connection elsewhere, or may be a functionally capable packaged chip as in a package-on-package (POP) assembly. The substrate may alternatively include a dielectric surface having exposed electrical contacts such as solder pads or microbumps known in the arts. A second chip attach adhesive material 24 is applied between the first adhesive 22 and the substrate 14, preferably on the surface 16 of the substrate 14. As appears in FIG. 2C, a laminated interposing layer 26 is constructed by bringing together the first chip attach adhesive material 20 and the second chip attach adhesive material 24. Preferably, debris particles 22, which may be present, are initially secured by the first chip attach adhesive material 20, (as indicated in FIGS. 2A-2C). The debris particles 22, should they become dislodged during placement of the chip 12, are further prevented from interfering with the surface below, e.g., 16, by the presence of the second chip attach adhesive material 24 (as indicated in FIG. 2C). Preferably, at least one of the chip attach materials is made from a film adhesive. If one film adhesive 20 and one non-film adhesive 24 are used, as in the example of FIGS. 2A-2C, their positions may be reversed without departure from the invention. The adhesive film 20 is preferably made from a polyimide (PET) film or similar material providing a thin flexible base as a vehicle for impregnation with suitable adhesive. An unexpected advantage of the invention, when suitable adhesive materials are used, is the high conformability of the laminated interposing layer 26 to the adjacent surfaces 12, 16, which provides mechanically strong bonds between the adjoining surfaces.

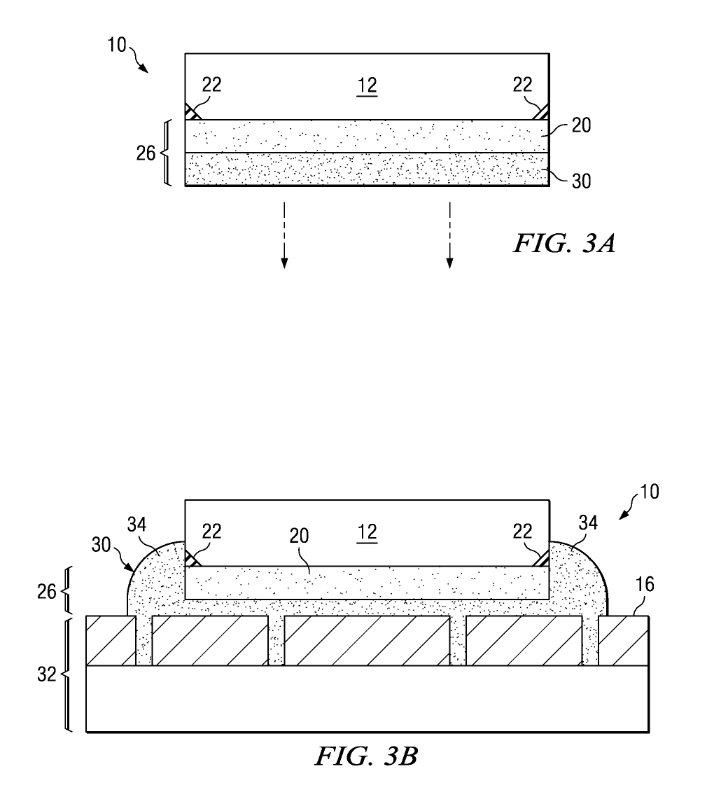

The possible variations of implementations of the invention are many and cannot, and need not, all be shown. An additional example of an alternative preferred embodiment of the invention possessing distinct advantages is shown in FIGS. 3A and 3B. The package assembly 10 has a first chip 12 with a laminated interposing layer 26 affixed to its surface as shown. The laminated interposing layer 26 has a first adhesive material, as shown in this example, a first adhesive film 20 preferably having relatively low elasticity properties. The laminated interposing layer 26 also has a second adhesive material, preferably an adhesive film 30 having relatively high elasticity. Now referring primarily to FIG. 3B, the first chip 12 and affixed laminated interposing layer 26 are in turn affixed to a second chip 32, although a substrate may also be substituted in place of an active chip 32. Thus, a layered package assembly 10 using a laminated interposing layer 26 is constructed wherein any debris particles 22, if present, e.g., as shown on the first chip 12, are held initially by the first adhesive material 20 and are ultimately captured by the second adhesive material 30. As shown, the relatively high elasticity second adhesive film 30 is preferably caused to conform somewhat to the shape of the first chip 12, by virtue of its high elasticity. The first adhesive material 20, due to a lower elasticity, preferably remains substantially unaffected by the application of force used to displace the second adhesive material 30 into the desired configuration. As shown in the somewhat exaggerated view of FIG. 3B, the second adhesive material 30 may be used to form a fillet 34 whereby the edges of the first chip 12 become engulfed, permanently capturing any debris particles, e.g., 22, which may be present, preventing them from later becoming dislodged and potentially coming into contact with the surface 16 of the second chip 32.

The illustrated embodiments of the laminated interposing layer of the invention are exhibited to possess unexpected advantages in terms of reductions in potential defects from debris in addition to other advantages referenced herein. The methods and laminated interposing layers of the invention provide one or more advantages such as, but not limited to, surprisingly effective reduction of debris problems, increased reliability, improved mechanical bonds between stack components, and reduced costs. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A semiconductor chip assembly comprising:
a semiconductor chip affixed to the surface of;
a substrate; and
a laminated interposing layer therebetween, the laminated interposing layer further comprising a first adhesive material and a second adhesive material.

2. The semiconductor chip assembly according to claim 1 wherein at least one of the first adhesive material or second adhesive material comprises an adhesive film.

3. The semiconductor chip assembly according to claim 1 wherein at least one of the first adhesive material or second adhesive material comprises a curable semi-viscous adhesive material.

4. The semiconductor chip assembly according to claim 1 wherein the first adhesive material and second adhesive material comprise adhesive films.

5. The semiconductor chip assembly according to claim 1 wherein the substrate comprises a second semiconductor chip.

6. The semiconductor chip assembly according to claim 1 wherein the substrate further comprises a conductive surface bonded to the laminated interposing layer.

7. The semiconductor chip assembly according to claim 1 wherein one of the adhesive materials further comprises a high elasticity adhesive.

8. A method for making a vertically stacked semiconductor chip assembly comprising the steps of:
applying a first adhesive material to a surface of a first semiconductor chip;
applying a second adhesive material to a surface of a substrate; thereafter,
joining the first and second adhesive materials to form a laminated interposing layer between the first chip and the substrate.

9. The method according to claim 7 wherein the semiconductor substrate further comprises a second semiconductor chip.

10. The method according to claim 7 wherein the interposing layer further comprises polyimide film.

11. The method according to claim 7 wherein at least one of the first adhesive material or second adhesive material comprises a curable semi-viscous adhesive material.

12. The method according to claim 7 wherein the substrate further comprises a conductive surface bonded to the laminated interposing layer.

13. The method according to claim 7 wherein the first adhesive material further comprises a low elasticity adhesive.

14. The method according to claim 7 wherein the second adhesive material further comprises a high elasticity adhesive.

15. The method according to claim 7 wherein at least one of the adhesive materials is applied to the substrate for shielding the substrate surface from debris during package assembly.

16. The method according to claim 7 wherein the second adhesive material is applied to the substrate for shielding the substrate surface from debris during package assembly.
